(19) United States
(12) Patent Application Publication
(10) Pub. No.: US 2026/0155493 A1
(43) Pub. Date: Jun. 4, 2026

(54) HEAT EXCHANGER WITH POWER MODULE COOLER

(71) Applicant: FORD GLOBAL TECHNOLOGIES, LLC, Dearborn, MI (US)

(72) Inventors: Ethan Filip, Indian Trail, NC (US); Diego Alberto Silva Rodriguez, Ben Lomond, CA (US); Hai Lan, Palo Alto, CA (US)

(21) Appl. No.: 19/400,282

(22) Filed: Nov. 25, 2025

Related U.S. Application Data
(60) Provisional application No. 63/726,413, filed on Nov. 29, 2024.

(51) Int. Cl. H01M 10/667; B60L 58/26; H01M 10/613; H01M 10/625; H01M 10/6554; H01M 10/6556; H01M 10/6568; H05K 7/20

(52) U.S. Cl. CPC H01M 10/667; B60L 58/26; H01M 10/613; H01M 10/625; H01M 10/6554; H01M 10/6556; H01M 10/6568; H05K 7/20254; H05K 7/20263; H05K 7/20272; H05K 7/20281; H05K 7/20927; B60L 2210/40; H01M 2220/20

(57) ABSTRACT

A vehicle includes an electric machine with an outer housing, a battery, and a heat exchanger positioned within the outer housing. An inverter is bonded directly to an outer surface of the heat exchanger. The inverter converts direct current from the battery into alternating current to drive the electric machine, while the heat exchanger removes heat generated by both the inverter and the electric machine.

### CROSS-REFERENCE TO RELATED APPLICATION

This application claims the benefit of U.S. Provisional Application Ser. No. 63/726,413, filed Nov. 29, 2024, the entire contents of which is hereby incorporated in its entirety by reference herein.

### TECHNICAL FIELD

The present disclosure relates to heat exchangers with integrated power modules for hybrid or electric vehicle powertrains, and more specifically to power modules that are mounted directly to a heat exchanger located within the powertrain.

### BACKGROUND

Vehicle drive units that include a motor, gearbox, and inverter may require cooled oil for gearbox lubrication and motor cooling, as well as liquid cooling for the inverter's power electronic switches.

### SUMMARY

A vehicle is equipped with an electric machine housed within an outer casing and propelled by power delivered through an inverter that is directly bonded to the outer surface of an internal heat exchanger. The inverter converts battery-supplied DC power into AC for the electric machine, while the heat exchanger removes heat from both components. In various embodiments, the heat exchanger includes liquid-cooling interfaces fluidly connected to a radiator, as well as oil-cooling passages that circulate oil between the exchanger and the electric machine at different temperature states. The exchanger may further be constructed from stacked, welded or bonded cooling plates that form separate, pressurizable flow paths incorporating S-shaped turbulators. The inverter may include multiple power electronic devices mounted on a bonding substrate formed from sintering, soldering, compression-fusing, or thermal-paste materials, with each device having connection pins for interfacing with a power control board.

A vehicle includes an electric machine, a transmission, and at least one inverter power electronic device all housed within a common outer housing and thermally managed by a heat exchanger positioned inside the housing. The inverter device is directly bonded to the heat exchanger, which is configured to remove heat from the inverter, the electric machine, and the transmission and transfer it to a radiator. In certain embodiments, the heat exchanger is constructed from stacked turbulator cooling plates bonded together to define two separate pressurized flow paths, one for a water-based coolant flowing to the radiator and the other for an oil-based coolant circulating through the electric machine and transmission. Each inverter power electronic device may be mounted to the heat exchanger via a bonding substrate formed from sintering, soldering, compression-fusing, or thermal-paste attachment materials, and may include connection pins for electrical communication with a power control board.

A heat exchanger is formed from a stack of turbulator plates positioned between two bonded outer plates that collectively define two internal flow paths. A first plate is bonded to one side of the stacked plates and a second plate is bonded to the opposite side, with the resulting structure establishing separate first and second flow paths routed between and around the turbulator plates. The first plate includes an inlet to the first flow path, while the second plate includes the corresponding outlet of the first flow path as well as the inlet and outlet for the second flow path. The heat exchanger is designed for integration within an electric machine housing, and at least one inverter power electronic device is directly bonded to an outer surface of one of the outer plates to support efficient thermal management.

### BRIEF DESCRIPTION OF THE DRAWINGS

FIG. 1 illustrates an example powertrain of an electric vehicle.

FIG. 2 illustrates a representative inverter circuit diagram of a power controller showing an inverter coupled to a DC power source and an electric machine.

FIG. 3 illustrates a perspective view of a powertrain assembly with an outer housing that encloses an electric motor, gearbox, and differential assembly, and includes an integrated inverter heat exchanger positioned within a cavity of the outer housing.

FIG. 4 illustrates, in cross-section, the integrated inverter heat exchanger assembly shown in FIG. 3.

FIG. 5 illustrates a perspective view of an inverter-integrated heat exchanger that includes stacked and brazed turbulator flow plates defining first and second flow paths, with inverter power modules bonded to an outer surface.

FIG. 6 illustrates an exploded view of the inverter-integrated heat exchanger of FIG. 5, with each stacked turbulator flow plate shown separately.

### DETAILED DESCRIPTION

The embodiments described herein are provided as examples and may be implemented in various other forms. The figures are not drawn to scale; certain features may be enlarged or reduced to illustrate particular components. Accordingly, the structural and functional details disclosed should not be interpreted as limiting, but as representative examples for enabling a person skilled in the art to implement the disclosed subject matter in different ways.

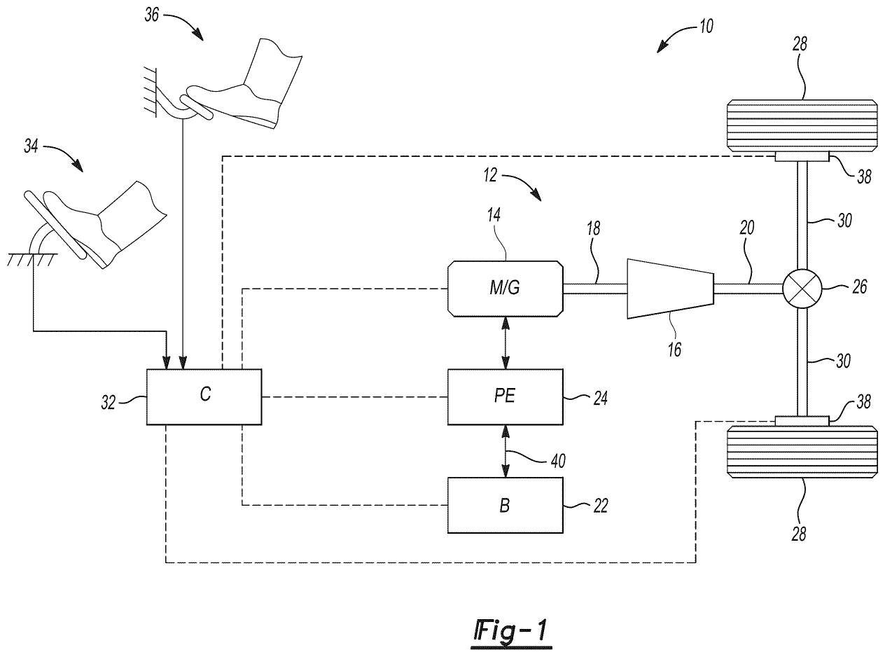

Referring to FIG. 1, a schematic diagram of an electric vehicle 10 is shown. The figure illustrates representative relationships among the components; their physical placement and orientation within the vehicle may vary, and some components may be combined into modules or housed together. The electric vehicle 10 includes a powertrain 12 having an electric machine, such as an electric motor/generator (M/G) 14, that drives a transmission (or gearbox) 16. The M/G 14 may be rotatably connected to an input shaft 18 of the transmission 16, or the M/G 14 and the gearbox 16 may be directly connected and packaged within a common housing.

The transmission 16 may be placed in PRNDSL (park, reverse, neutral, drive, sport, low) using a transmission range selector (not shown). It may provide a fixed gear ratio between the input shaft 18 and an output shaft 20, or it may be configured as a multi-step automatic transmission or a continuously variable transmission (CVT). A torque converter (not shown) or a launch clutch (not shown) may be positioned between the M/G 14 and the transmission 16.

A traction battery 22 supplies electrical power to the M/G 14 and may also receive electrical power recovered through regenerative operation.

The M/G 14 serves as the drive source for the electric vehicle 10 and is configured to propel the vehicle. The M/G 14 may be implemented using various types of electric machines; for example, it may be a permanent magnet synchronous motor. Power electronics 24 condition the direct current (DC) supplied by the battery 22 to meet the operating requirements of the M/G 14. In one example, the power electronics 24 include an inverter that converts DC power to three-phase alternating current (AC) for delivery to the M/G 14, as described in greater detail below.

If the transmission 16 is a multi-step-ratio automatic transmission, it may include gear sets (not shown) that are shifted into different ratios by selectively engaging friction elements such as clutches (not shown). These friction elements are controlled according to a shift schedule that connects and disconnects components of the gear sets to establish the desired ratio between the transmission input shaft 18 and output shaft 20. The transmission 16 automatically shifts between ratios based on vehicle and environmental operating conditions under the control of a powertrain control unit (PCU) or other suitable controller. Power and torque from the M/G 14 may be delivered to the transmission 16 or received from it, and the transmission 16 in turn supplies output power and torque to the output shaft 20.

The hydraulically controlled transmission 16, which may be paired with a torque converter (not shown), is only one example of a suitable gearbox configuration. Any multi-ratio gearbox that receives input torque from a power source (e.g., the M/G 14) and delivers torque to an output shaft (e.g., the output shaft 20) at different gear ratios may be used with the embodiments described herein. For example, the transmission 16 may be implemented as an automated mechanical transmission (AMT) that uses one or more servo motors to move shift forks along a shift rail to select the desired gear ratio. As is generally understood, AMTs may be used in applications requiring higher torque, among other use cases.

In the representative embodiment shown in FIG. 1, the output shaft 20 is connected to a differential 26. The differential 26 drives a pair of wheels 28 through respective axles 30 and distributes approximately equal torque to each wheel while allowing speed differences, such as during cornering. Various types of differentials or similar torque-distribution devices may be used, and in some configurations the torque split may vary depending on operating conditions or drive modes.

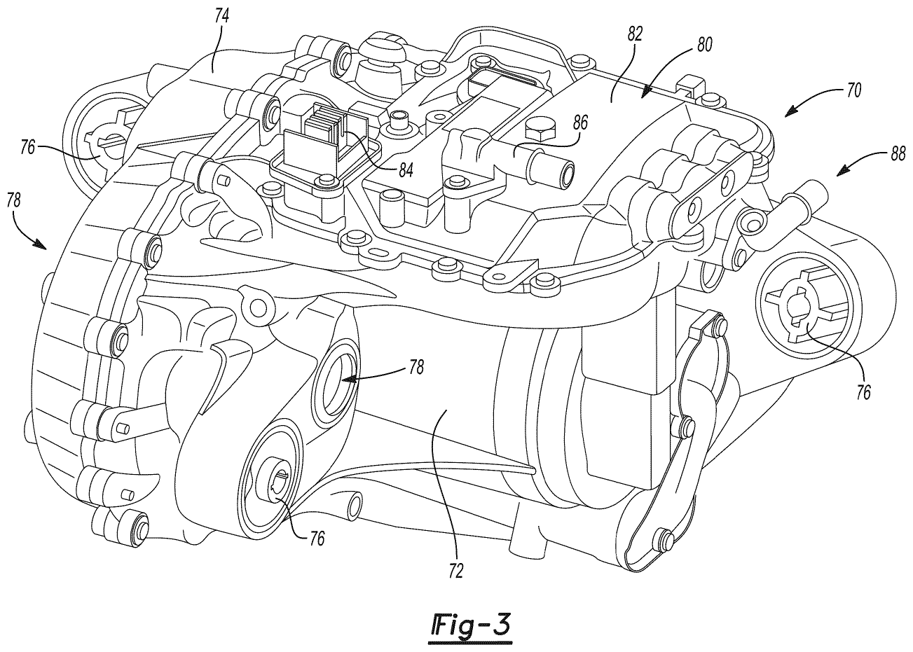

FIG. 1 depicts the M/G 14, gearbox 16, power electronics 24, input shaft 18, output shaft 20, and differential 26 as separate components. However, these components may instead be packaged together within a single housing 60 (shown in FIG. 3), with the axles 30 extending from the housing to drive the wheels 28. In such a configuration, the M/G 14 may be directly coupled to the transmission 16 through the shaft 18, and the differential 26 may also be integrated within the single housing 60, as described in greater detail below.

The powertrain 12 also includes a controller 32, such as a powertrain control unit (PCU). Although shown as a single controller, the controller 32 may operate as part of a larger control architecture and may coordinate with other vehicle controllers, such as a vehicle system controller (VSC). Accordingly, the controller 32 and any associated controllers may collectively be referred to as the “controller,” which operates various actuators based on sensor inputs to perform functions such as commanding the M/G 14 to provide wheel torque or charge the battery 22, and selecting or scheduling transmission shifts.

The controller 32 may include a microprocessor or central processing unit (CPU) in communication with various types of computer-readable storage media. Such media may include both volatile and non-volatile memory, such as read-only memory (ROM), random-access memory (RAM), and keep-alive memory (KAM). KAM is a persistent memory used to store operating variables while the CPU is powered down. The storage media may be implemented using known memory devices, including programmable ROM (PROM), electrically programmable ROM (EPROM), electrically erasable ROM (EEPROM), flash memory, or other electric, magnetic, optical, or hybrid memory capable of storing data, including executable instructions, used by the controller to manage powertrain or vehicle operation.

The controller 32 communicates with various vehicle sensors and actuators through an input/output (I/O) interface that includes input and output channels. The I/O interface may be implemented as a single integrated module that provides raw data acquisition, signal conditioning, processing, conversion, short-circuit protection, and similar functions. Alternatively, certain signals may be conditioned or processed by dedicated hardware or firmware components before being delivered to the CPU.

As generally shown in FIG. 1, the controller 32 may send signals to and/or receive signals from the M/G 14, battery 22, transmission 16, power electronics 24, and other powertrain components not explicitly illustrated, such as a launch clutch located between the M/G 14 and the transmission 16. Those of ordinary skill in the art will recognize the various functions and subsystems within these components that may be managed by the controller 32.

Examples of systems or parameters that may be directly or indirectly controlled through logic or algorithms executed by the controller 32 include front-end accessory drive (FEAD) components such as an alternator or air-conditioning compressor, battery charging and discharging, regenerative braking, M/G 14 operation, and clutch pressures in the transmission gearbox 16 or other powertrain clutches.

Sensors providing inputs through the I/O interface may include sensors for wheel speed (WS1, WS2), vehicle speed (VSS), coolant temperature (ECT), pedal position (PPS), ignition switch position (IGN), ambient air temperature (e.g., sensor 33), transmission gear, ratio, or mode, transmission oil temperature (TOT), transmission input and output speeds, shift mode (MDE), and battery temperature, voltage, current, or state of charge (SOC), among others.

The control logic executed by the controller 32 may be illustrated in flow charts or similar diagrams. These figures depict representative control strategies that may be implemented using various processing approaches, such as event-driven, interrupt-driven, multi-tasking, or multi-threading techniques. Accordingly, the steps shown may be performed in the order illustrated, in parallel, or in some cases omitted altogether. One of ordinary skill in the art will also recognize that certain steps may be repeated depending on the processing strategy employed. The sequence is therefore provided for ease of explanation rather than to indicate a required order.

The control logic may be implemented primarily in software executed by a microprocessor-based vehicle or powertrain controller, such as the controller 32. However, it may also be implemented in hardware or in a combination of hardware and software, depending on the application. When implemented in software, the logic may be stored on one or more computer-readable storage media containing code or instructions executed by the controller to manage vehicle or powertrain functions. Such storage media may include known electric, magnetic, or optical memory devices used to store executable instructions, calibration data, operating variables, and related information.

A driver-operated pedal 34 is used to request torque, power, or a drive command from the powertrain 12, and specifically from the M/G 14, to propel the vehicle. Depressing or releasing the pedal 34 generates a position signal that the controller 32 interprets as a request for increased or decreased power, respectively. A pedal 36 allows the driver to request torque to slow the vehicle. Depressing or releasing the pedal 36 produces a pedal position signal interpreted by the controller 32 as a request to reduce vehicle speed.

Based on inputs from the pedal 34 and the pedal 36, the controller 32 commands torque and power delivery from the M/G 14 and controls actuation of friction elements 38. The controller 32 also manages the timing of gear shifts within the transmission 16.

The M/G 14 may operate as a motor to provide driving torque to the powertrain 12. In this mode, the traction battery 22 supplies electrical energy through wiring 40 to the power electronics 24, which may include inverter and rectifier circuitry. The inverter converts the DC voltage from the battery 22 into AC voltage for use by the M/G 14. The rectifier circuitry may perform the opposite conversion, converting AC voltage from the M/G 14 into DC voltage for storage in the battery 22. The controller 32 commands the power electronics 24 to convert battery voltage into the appropriate AC voltage needed to apply positive or negative torque to the input shaft 18.

The M/G 14 may also operate as a generator, converting kinetic energy from the powertrain 12 into electrical energy that is stored in the battery 22. During regenerative braking, rotational energy from the wheels 28 is transferred through the transmission 16 to the M/G 14, which converts this mechanical energy into electrical energy for battery charging.

The vehicle configuration described above is merely illustrative. Other electric or hybrid vehicle architectures may also be used. Examples include series hybrid vehicles, parallel hybrid vehicles, series-parallel hybrid vehicles, plug-in hybrid electric vehicles (PHEVs), fuel cell hybrid vehicles, battery electric vehicles (BEVs), and other configurations known to those of ordinary skill in the art.

In hybrid configurations that include an internal combustion engine, such as a gasoline, diesel, natural-gas engine, or a fuel cell, the controller 32 may also control various engine operating parameters. Examples of internal combustion engine parameters and systems that may be directly or indirectly controlled by logic executed by the controller 32 include fuel injection timing, rate, and duration; throttle valve position; ignition timing in spark-ignition engines; and intake and exhaust valve timing and duration. Sensors associated with the engine may provide inputs to the controller 32 through the I/O interface, such as turbocharger boost pressure, crankshaft position (PIP), engine speed (RPM), intake manifold pressure (MAP), throttle position (TP), exhaust gas oxygen amount or other exhaust gas constituents, and intake air flow (MAF).

The schematic shown in FIG. 1 is representative and not limiting. Other configurations may be used without departing from the scope of this disclosure. For example, the powertrain 12 may be configured to deliver power and torque to the front wheels instead of the rear wheels 28 illustrated.

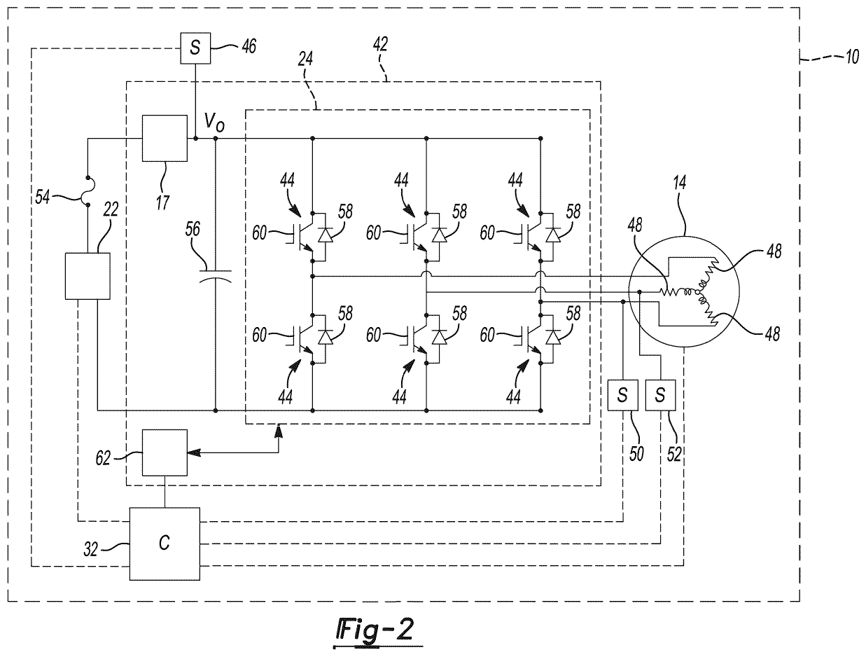

Referring to FIG. 2, a circuit diagram of an example power electronics controller (or power supply device) 42 coupled to the battery 22 and the M/G 14 is shown. The power electronics, or inverter 24, includes inverting circuitry made up of switching units 44. Each switching unit 44 may include a transistor 60, such as an insulated gate bipolar transistor (IGBT), connected in antiparallel with a diode 58. These switching units 44 generate alternating current for the electric machine 14.

A linking capacitor 56 is positioned between the battery 22 and the inverter 24. The capacitor 56 absorbs ripple currents generated by either the inverter 24 or the battery 22 and stabilizes the DC-link voltage Vo for inverter operation. Stated differently, the capacitor 56 limits voltage variation at the input of the inverting circuitry caused by ripple currents.

The power electronics controller 42 may include a PCB drive board 62 configured to operate the transistors 60 of the switching units 44. This gate-drive board controls the conversion of DC power from the battery 22 into AC power delivered to the electric machine 14.

A voltage converter 17, such as a DC-to-DC converter that may include an inductor, may also be provided. The voltage converter 17 may be integrated with the power electronics controller 42 or configured as a separate component. The inverter 24 and the voltage converter 17 may supply electrical power to the electric machine 14. The converter circuitry (not shown), including the inductor, may increase the voltage delivered from the battery 22 to the electric machine 14. A fuse 54 may be placed on the DC side of the inverter 24 to protect the inverting circuitry from electrical surges.

The disclosure is not limited to the specific circuit configuration illustrated. Other combinations of inverters, capacitors, converters, or similar components may be used. For example, the inverter 24 may include any number of switching units, and the linking capacitor 56 may couple one or multiple inverters to the battery.

DC power delivered to the inverter 24 may be measured by a first sensor 46 located at the inverter input. AC power delivered to the winding phases 48 of the electric machine 14 may be measured by a second sensor 50 and a third sensor 52, which monitor the alternating current supplied to two of the three phases. The alternating current in the third phase may be estimated from these two measurements. The controller 42 may execute an algorithm that converts the measured currents into a corresponding torque or power output of the electric machine 14.

The disclosure should not be limited to the circuit diagram of FIG. 2 and encompasses power control devices incorporating other inverter, capacitor, or converter configurations, or combinations thereof. Additionally, the components of the power controller 10 shown in FIGS. 1 and 2 may be implemented as common or separate components, and the examples provided are not intended to be limiting.

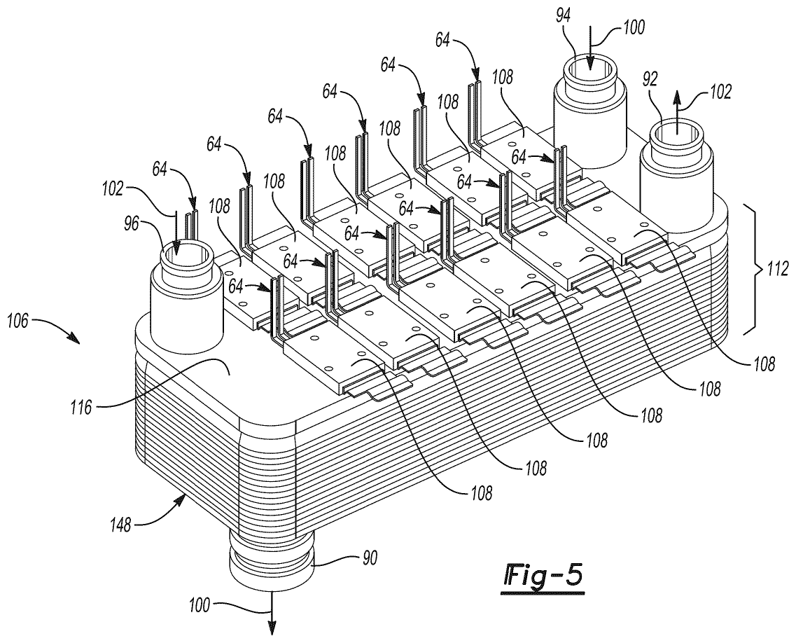

FIGS. 3 to 6 and the accompanying description present an example powertrain assembly that incorporates an integrated heat exchanger assembly and its individual components. The integrated heat exchanger assembly includes inverter power electronics mounted directly to the heat exchanger, such as the power electronics inverter 24 described above, or may be configured for other types of power electronics.

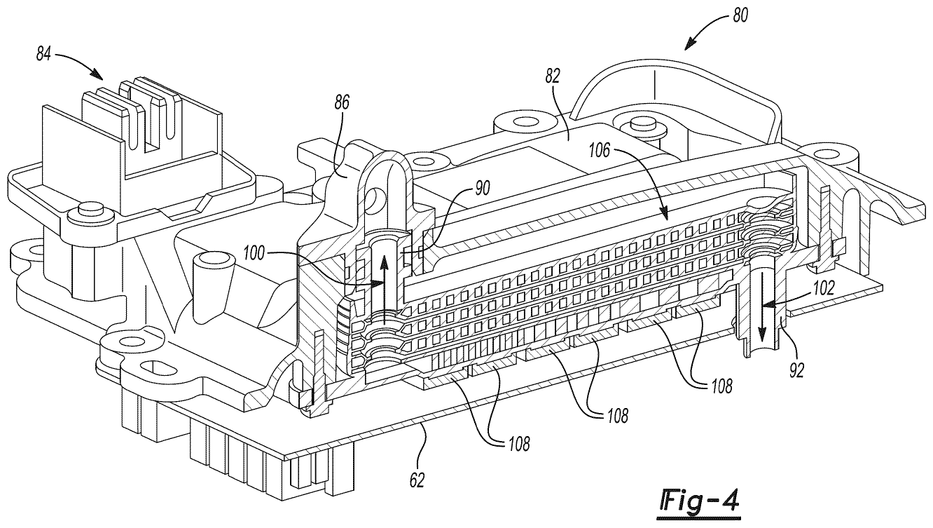

Referring to FIGS. 3 and 4, a powertrain assembly 70 may include a two-piece outer housing formed by a casing 72 and a removable casing cover 74 that seals the assembly. The casing 72 includes a cavity (not shown) that houses one or more of the M/G 14, gearbox 16, and differential 26, allowing these components to be packaged together as a single unit for installation in the electric vehicle 10.

An inverter heat exchanger assembly 80 is also provided and is shown mounted to, and extending at least partially through, an outer surface of the casing 72. In alternative configurations, the heat exchanger assembly 80 may be attached through the casing cover 74 or inserted directly into the cavity when the M/G 14 is installed, eliminating the need for the assembly to extend through the outer surface of the casing.

The powertrain assembly 70 may further include multiple support mounts 76 integrated into the casing 72 and the casing cover 74, providing attachment points for securing the assembly within the vehicle. As shown, the assembly also includes axle receiving sockets 78 that are rotatably coupled to the gearbox 16 and configured to receive the axles 30, which transfer rotational output from the M/G 14 to propel the vehicle.

The inverter heat exchanger assembly 80 may include a heat exchanger cover 82 that attaches to the powertrain assembly 70 and supports several components, including a DC power input connector 84, an inverter heat exchanger module 106, and the PCB drive board 62 with associated inverter electronics. The heat exchanger cover 82 also provides a fluid connection through a liquid-cooling outlet housing 86, allowing an external vehicle radiator (not shown) to supply coolant to a first flow path 100 within the inverter heat exchanger module 106. Coolant enters the first flow path 100 through a liquid-cooling input housing 88 that extends through the outer casing 72 and fluidly connects to the inverter heat exchanger module 106.

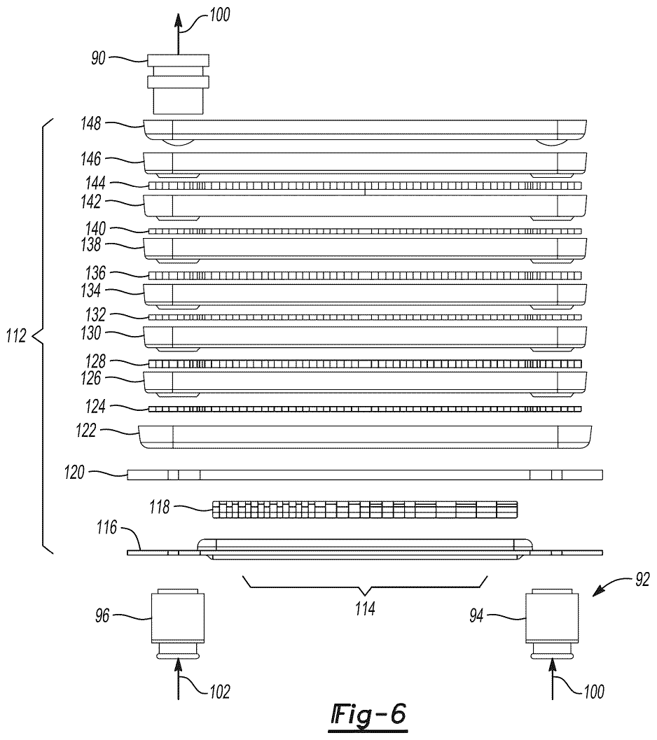

As previously noted, components of the inverter heat exchanger assembly 80 extend into the interior cavity and are electrically and fluidly connected to at least the M/G 14 to deliver AC power and provide cooling to the lubricant or oil circulating through the M/G 14 and/or the gearbox 16 and differential 26. As shown in the sectional view of FIG. 4 and the exploded view of FIG. 6, the inverter heat exchanger module 106 may be constructed as a stack of cooling plates and turbulators brazed or fused together to form a heat exchanger stack 112. The turbulators may have an S-shaped cross-section (not shown) that defines multiple internal cooling channels, creating two separate flow paths 100 and 102 for cooling both the powertrain assembly 70 and the inverter electronics 108. These electronics may be bonded directly to an interface plate 116 using a bonding substrate and bonding technique such as sintering, compression bonding, soldering, or thermal-paste bonding.

As illustrated in FIGS. 4-6, the heat exchanger stack 112 may include, in this example, the interface plate 116 with bonded inverter electronics 108, an inverter electronics turbulator 118, a mount plate 120, a core base plate 122, a first cooling-liquid turbulator 124 and plate 126, a first oil turbulator 128 and plate 130, a second cooling-liquid turbulator 132 and plate 134, a second oil turbulator 136 and plate 138, a third cooling-liquid turbulator 140 and plate 142, a third oil turbulator 144 and plate 146, and a final thick plate 148. Other plate counts and configurations may also be used.

After the stack elements are brazed or fused together to form the heat exchanger stack 112, and the liquid and oil inlet/outlet tubes 90, 92, 94, and 96 are brazed to the stack to create the inverter heat exchanger module 106, multiple internal cooling channels are defined. These channels may be microchannels, each having a hydraulic diameter below 1 millimeter.

The first flow path 100 extends from the cooling-liquid inlet tube 94, through the liquid turbulators 124, 132, and 140, and exits at the cooling-liquid outlet tube 90. The second flow path 102 extends from the oil inlet tube 96, through the oil turbulators 128, 136, and 144, and exits at the oil outlet tube 92. The cooling liquid may be glycol or another coolant commonly used in electric vehicles, and the oil may be any lubricating oil suitable for electric vehicle applications. The cooling-liquid inlet tube 94 and outlet tube 90 are fluidly connected to the vehicle radiator, while the oil inlet tube 96 and outlet tube 92 are fluidly connected to one or more of the M/G 14, gearbox 16, and differential 26.

During operation, a first pump (not shown) may circulate oil through the second flow path 102, and a second pump (not shown) may circulate cooling liquid through the first flow path 100. As the liquids pass through their respective turbulators, heat is transferred while maintaining a pressurized environment inside the inverter heat exchanger module 106.

Heat enters the heat exchanger in several ways. First, the inverter electronics 108 generate heat while converting DC power to AC power. Second, oil returning from the M/G 14, gearbox 16, or differential 26 enters the module at an elevated temperature due to mechanical work and associated losses. Additional heat may arise from fluid movement through the system. Heat is removed as the stacked turbulators 118, 124, 128, 132, 136, 140, and 144, along with the adjacent oil plates 130, 138, 146 and liquid-cooling plates 126, 134, 142, transfer heat from the inverter electronics and the oil to the heat exchanger, while the coolant carries the heat away to the radiator.

In operation, oil enters the heat exchanger at an elevated temperature and flows through the second flow path 102, where heat is removed by the cooling liquid flowing through the first flow path 100. The same heat-transfer principle applies to the inverter electronics 108. Cooling liquid passes through the inverter turbulator 118 in the first flow path 100, absorbs heat, and transports it to the vehicle radiator. The coolant therefore enters the heat exchanger at a lower temperature and exits at a higher temperature, eliminating the need for a separate cooling plate dedicated solely to the inverter.

While example embodiments are described above, they are not intended to represent all possible forms that the disclosed subject matter may take. The terminology used herein is intended for description rather than limitation, and various modifications may be made without departing from the scope of the disclosed subject matter. Additionally, features from different embodiments may be combined to create further embodiments.

What is claimed is:

1. A vehicle comprising:
an electric machine including an outer housing and configured to propel the vehicle;
a heat exchanger disposed within the outer housing; and
an inverter bonded directly to an outer surface of the heat exchanger and configured to convert direct current from a battery into alternating current for the electric machine, wherein the heat exchanger is configured to remove heat from the inverter and the electric machine.

2. The vehicle of claim 1 further comprising a radiator fluidly connected to a liquid cooling inlet and a liquid cooling outlet defined on the heat exchanger.

3. The vehicle of claim 1, wherein the heat exchanger further includes an oil inlet and an oil outlet defined on the heat exchanger, wherein the oil outlet is configured to transfer an oil in a first temperature state from the heat exchanger to the electric machine, wherein the oil inlet is configured to transfer the oil in a second temperature state from the electric machine to the heat exchanger, and wherein the second temperature state is greater than the first temperature state.

4. The vehicle of claim 1, wherein the heat exchanger includes a plurality of stacked cooling plates defining separate cooling channels, wherein the separate cooling channels define a first flow path and a second flow path, and wherein the first flow path is separate from the second flow path.

5. The vehicle of claim 4, wherein the separate cooling channels include a plurality of turbulators having “S” shaped cross-sections.

6. The vehicle of claim 4, wherein the stacked cooling plates are welded, braised, or bonded together to create the first flow path and the second flow path.

7. The vehicle of claim 4, wherein the separate cooling channels are configured to be pressurized.

8. The vehicle of claim 1, wherein the inverter includes a plurality of inverter power electronic devices and a bonding substrate.

9. The vehicle of claim 8, wherein the bonding substrate includes a sintering attachment material, soldering attachment material, compression fusing attachment material, or thermal paste fusing attachment material.

10. The vehicle of claim 8, wherein each of the inverter power electronic devices includes at least one connection pin configured to connect at least one of the inverter power electronic devices to a power control board.

11. A vehicle comprising:
an electric machine including an outer housing, a heat exchanger disposed within the outer housing, and at least one inverter power electronic device directly bonded to the heat exchanger; and
a transmission rotatably connected to the electric machine and disposed within the outer housing, wherein the heat exchanger is configured to transfer heat from at least one of the electric machine, the transmission, or the at least one inverter power electronic device to a radiator.

12. The vehicle of claim 11, wherein the heat exchanger includes a plurality of stacked turbulator cooling plates that are bonded together and define a first pressurized flow path and a separate second pressurized flow path.

13. The vehicle of claim 12, wherein the radiator is fluidly connected to at least one of the first pressurized flow path or the second pressurized flow path, and wherein the electric machine and the transmission are fluidly connected to the other of the at least one of the first pressurized flow path or the second pressurized flow path such that when the radiator is fluidly connected to the first pressurized flow path, the electric machine is fluidly connected to the second pressurized flow path.

14. The vehicle of claim 12, wherein the first pressurized flow path defines a channel to flow a water-based cooling liquid through the radiator and the second pressurized flow path defines a channel to flow an oil-based cooling liquid through the electric machine and transmission.

15. The vehicle of claim 11 further comprising a bonding substrate configured to bond each of the at least one inverter power electronic devices to an outer surface of the heat exchanger.

16. The vehicle of claim 15, wherein the bonding substrate includes a sintering attachment, soldering attachment, compression fusing attachment, or thermal paste fusing attachment to bond each of the at least one inverter power electronic device to the outer surface.

17. The vehicle of claim 15, wherein the at least one inverter power electronic device includes at least one connection pin configured to be in electronic communication with a power control board.

18. A heat exchanger comprising:
a plurality of stacked turbulator plates;
a first plate bonded to a side of the stacked turbulator plates;
a second plate bonded to an opposite side of the stacked turbulator plates, wherein the first and second plates define, at least partially, a first flow path and a second flow path within the heat exchanger; and
at least one inverter power electronic device disposed within an electric machine housing and bonded to an outer surface of at least one of the first and second plates.

19. The heat exchanger of claim 18, wherein the first flow path and the second flow path are two separate flow paths, each defined between and around the stacked turbulator plates and within the first and second plates, wherein an inlet of the first flow path is defined through the first plate, and wherein an outlet of the first flow path, an inlet of the second flow path, and an outlet of the second flow path are defined through the second plate.
